(19) United States
(12) Patent Application Publication
(10) Pub. No.: US 2025/0017091 A1
(43) Pub. Date: Jan. 9, 2025

(54) METHOD FOR MANUFACTURING PEROVSKITE SOLAR CELL

(71) Applicant: JUSUNG ENGINEERING CO., LTD., Gwangju-si, Gyeonggi-do (KR)

(72) Inventors: Jae Ho KIM, Gwangju-si, Gyeonggi-do (KR); Chul Joo HWANG

(21) Appl. No.: 18/708,587

(22) PCT Filed: Dec. 20, 2022
(86) PCT No.: PCT/KR2022/020808

§ 371 Date: May 8, 2024

(30) Foreign Application Priority Data
Dec. 20, 2021 (KR) 10-2021-0182673

(51) Int. Cl. H10K 71/16

(52) U.S. Cl. CPC H10K 71/166

(57) ABSTRACT

The present inventive concept comprises the steps of preparing a substrate on which a first conductive charge transport layer is formed; positioning a mask having an opening pattern on the substrate; and forming a perovskite layer on the substrate and the mask.

### TECHNICAL FIELDS

The present inventive concept relates to a perovskite solar cell, and more particularly, to a method for manufacturing a perovskite solar cell in which a plurality of unit cells are connected in series.

### BACKGROUND ART

A perovskite solar cell includes a light absorbing layer made of a perovskite compound, and conventionally, the light absorbing layer made of the perovskite compound is mainly formed through a solution process.

The solution process comprises dissolving a perovskite compound in a predetermined solvent to form a perovskite solution and applying the perovskite solution to a substrate by a method such as spin coating, spray coating, or slot die.

Meanwhile, in manufacturing a perovskite solar cell, there is a method of connecting a plurality of unit cells in series to improve efficiency. For this, a process of patterning the light absorption layer formed by the solution process is required. A laser scribing process is performed for the process of patterning. In this case, the perovskite compound constituting the light absorption layer may be adversely affected.

### DISCLOSURE

### Technical Problem

The present inventive concept is devised to solve the above-described problem, and it is an object of the present inventive concept to provide a method of manufacturing a perovskite solar cell, in which a plurality of unit cells are connected in series by patterning a light absorption layer made of a perovskite compound without performing a laser scribing process.

### Technical Solution

In order to achieve the above object, according to an embodiment of the present inventive concept, a method of manufacturing a perovskite solar cell comprises a step of preparing a substrate on which a first conductive charge transport layer is formed; a step of positioning a mask having an opening pattern on the substrate; and a step of forming a perovskite layer on the substrate and the mask.

The step of forming a perovskite layer may be performed at a pressure lower than an atmospheric pressure.

The step of positioning a mask having an opening pattern may include bringing the substrate and the mask into close contact with electrostatic force.

The method may further comprise a step of separating the perovskite layer for a plurality of unit cells by removing the mask and remaining the perovskite layer on the substrate.

The mask may include an edge mask pattern, a contact mask pattern, and a separator mask pattern, the edge mask pattern may be formed on one end and the other end of the substrate, and the contact mask pattern and the separator mask pattern may be formed to be spaced apart from each other at a center side of the substrate.

The method may further comprise a step of forming a second conductive charge transport layer on the substrate and the mask before the step of removing the mask, and a step of separating the second conductive charge transport layer for a plurality of unit cells by remaining the second conductive charge transport layer on the substrate during the step of removing the mask.

According to an embodiment of the present inventive concept, a method of manufacturing a perovskite solar cell comprises a step of preparing a substrate; a step of positioning a mask having an opening pattern on the substrate; and a step of forming a first conductive charge transport layer and a perovskite layer on the substrate and the mask.

The step of forming a perovskite layer may be performed at a pressure lower than an atmospheric pressure.

The step of positioning a mask having an opening pattern may include bringing the substrate and the mask into close contact with electrostatic force.

The method may further comprise a step of separating the perovskite layer for a plurality of unit cells by removing the mask and remaining the perovskite layer on the substrate.

The mask may include an edge mask pattern, a contact mask pattern, and a separator mask pattern, the edge mask pattern may be formed on one end and the other end of the substrate, and the contact mask pattern and the separator mask pattern may be formed to be spaced apart from each other at a center side of the substrate.

The method may further comprise a step of forming a second conductive charge transport layer on the substrate and the mask before the step of removing the mask, and a step of separating the second conductive charge transport layer for a plurality of unit cells by remaining the second conductive charge transport layer on the substrate during the step of removing the mask.

According to an embodiment of the present inventive concept, a method of manufacturing a perovskite solar cell comprises a step of positioning a first mask on a substrate and forming a first electrode layer separated by a plurality of unit cells using the first mask; a step of positioning a second mask on the first electrode layer and forming a first conductive charge transport layer, a light absorption layer made of a perovskite compound, and a second conductive charge transport layer, each of which is separated for the plurality of unit cells, using the second mask; and a step of positioning a third mask on the first electrode layer and forming a second electrode layer separated for the plurality of unit cells using the third mask.

The first mask may include a first edge mask pattern formed on one end and the other end of the substrate and a first separator mask pattern formed on a center of the substrate, the second mask may include a second edge mask pattern formed at one end and the other end of the substrate, and a second contact mask pattern and a second separator mask pattern formed at a center of the substrate to be spaced apart from each other, and the third mask may include a third edge mask pattern formed on one end and the other end of the substrate and a third separator mask pattern formed on a center of the substrate.

The plurality of first electrode layers may be separated with a first separator interposed therebetween, the plurality of second electrode layers may be separated with a second separator interposed therebetween, the second electrode layer in one unit cell may be connected to the first electrode layer in another adjacent unit cell through a contact portion, the first separator mask pattern may correspond to the first separator, the second separator mask pattern and the third separator mask pattern may correspond to the second separator, and the second contact mask pattern may correspond to the contact portion.

A third separator for preventing short circuit may be further provided in an area corresponding to the first edge mask pattern.

The second edge mask pattern and the third edge mask pattern may be formed to overlap with a portion of the first electrode layer provided at an outermost side, and a first terminal may be formed in a region overlapped with the portion of the first electrode layer. The second contact mask pattern and the second edge mask pattern may be formed on the remaining first electrode layers except for one first electrode layer provided at an outermost side.

### Advantageous Effect

According to the present inventive concept as described above, there are the following effects.

According to one embodiment of the present inventive concept, a perovskite solar cell in which a plurality of unit cells are connected in series without a laser scribing process may be obtained by patterning a light absorption layer made of a perovskite compound using a mask such as a shadow mask.

### DESCRIPTION OF DRAWINGS

FIGS. 1a to 1j are process cross-sectional views illustrating a method of manufacturing a perovskite solar cell according to an embodiment of the present inventive concept.

### MODE FOR THE INVENTIVE CONCEPT

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present specification are used, another part may be added unless “only” is used. The terms of a singular form may include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts may be disposed between the two parts unless a more limiting term, such as “just” or “direct(ly)” is used.

In describing a time relationship, for example, when the temporal order is described as, for example, “after,” “subsequent,” “next,” and “before,” a case that is not continuous may be included unless a more limiting term, such as “just,” “immediate(ly),” or “direct(ly)” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other, and may be variously inter-operated with each other and driven technically as those skilled in the art may sufficiently understand. The embodiments of the present disclosure may be carried out independently from each other, or may be carried out together in co-dependent relationship.

Hereinafter, embodiments of the present disclosure will be described in detail with reference to the accompanying drawings. In adding reference numerals to elements of each of the drawings, although the same elements are illustrated in other drawings, like reference numerals may refer to like elements.

Hereinafter, a preferable embodiment of the present inventive concept will be described in detail with reference to the accompanying drawings.

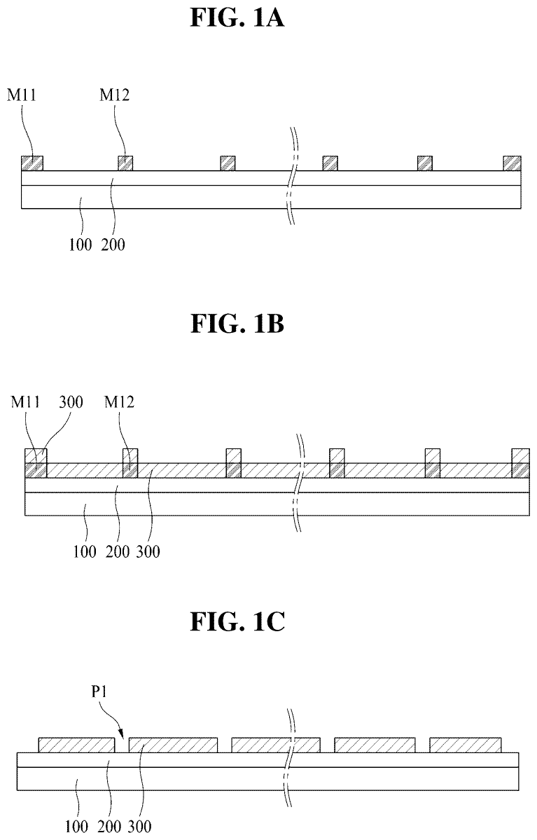

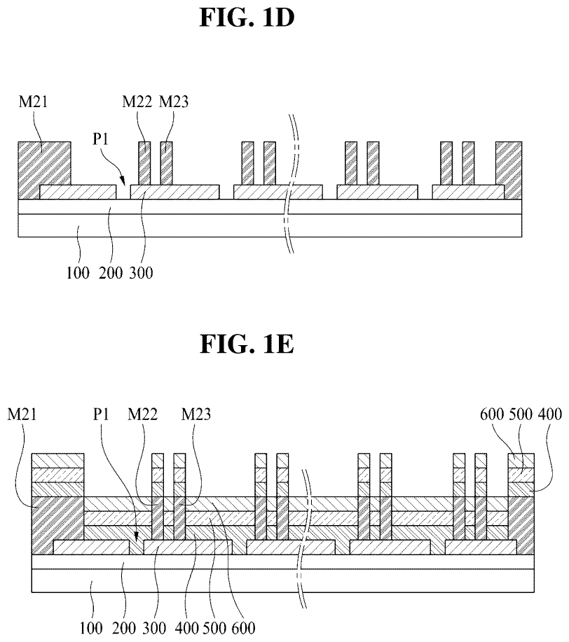

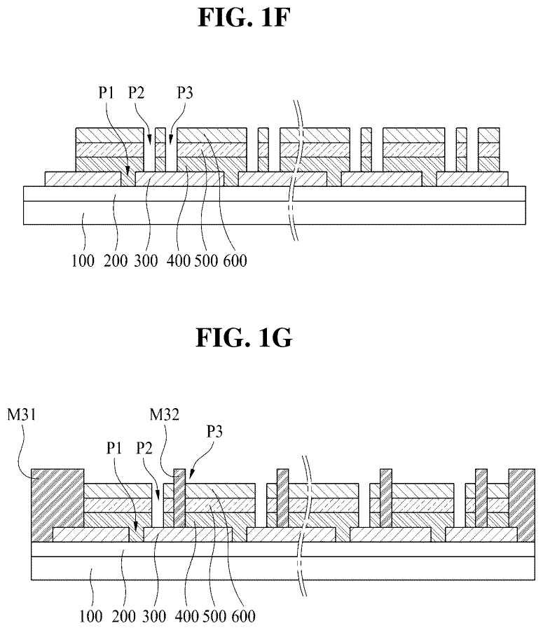

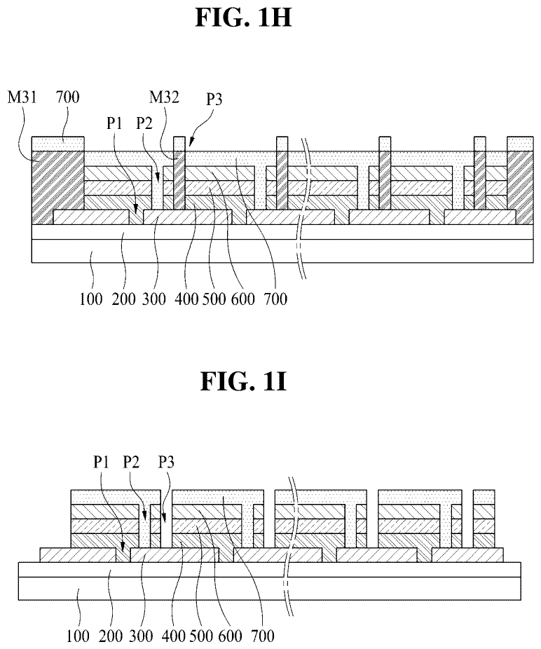

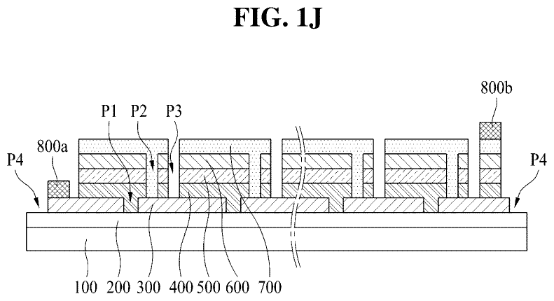

FIGS. 1a to 1j are process cross-sectional views illustrating a method of manufacturing a perovskite solar cell according to an embodiment of the present inventive concept.

First, as seen in FIG. 1a, a barrier layer 200 is formed on a substrate 100 and first masks M11 and M12 are positioned on the barrier layer 200.

The process of forming the barrier layer 200 may be performed at a pressure lower than an atmospheric pressure in a thin film deposition chamber after positioning the substrate 100 in the thin film deposition chamber. A process of positioning the first masks M11 and M12 may also be performed in the thin film deposition chamber. In this case, the process of positioning the first masks M11 and M12 may include a process of bringing the barrier layer or the substrate 100 and the first masks M11 and M12 into close contact with each other using electrostatic force.

The substrate 100 may be made of a rigid material or a flexible material. For example, the substrate 100 may be made of glass or plastic.

The barrier layer 200 is formed on one surface, for example, an upper surface of the substrate 100. The barrier layer 200 serves to prevent a material included in the substrate 100 from diffusing upwards from the substrate 100 in a subsequent process, and also prevents external moisture or oxygen from penetrating into an upper part of the substrate 100. The barrier layer 200 may be formed on the entire upper surface of the substrate 100.

The barrier layer 200 may be made of an inorganic insulating material such as silicon oxide, silicon nitride, metal oxide such as aluminum oxide, and metal nitride such as aluminum nitride, and may be formed through various thin film deposition processes known in the art, such as chemical vapor deposition (CVD) or atomic layer deposition (ALD). However, the barrier layer 200 may be omitted.

The first masks M11 and M12 are positioned on one surface, for example, an upper surface of the barrier layer 200.

The first masks M11 and M12 include a first edge mask pattern M11 and a first separator mask pattern M12. Portions not provided with the first edge mask pattern M11 and the first separator mask pattern M12 become opening patterns of the first masks M11 and M12. The first edge mask pattern M11 is formed to correspond to one end and the other end of the substrate 100 or the barrier layer 200. The first separator mask pattern M12 is between the first edge mask pattern M11 at one end and the first edge mask pattern M11 at the other end. That is, a plurality of the first separator mask pattern M12 are formed at a center of the substrate 100 or the barrier layer 200 with a predetermined interval. The width of the first edge mask pattern M11 may be greater than that of the first separator mask pattern M12.

As the first masks M11 and M12, a shadow mask known in the art may be used.

Next, as seen in FIG. 1b, a first electrode layer 300 is formed on one surface, for example, an upper surface of the substrate 100 or the barrier layer 200.

The process of forming the first electrode layer 300 may be performed at a pressure lower than an atmospheric pressure in the thin film deposition chamber.

The first electrode layer 300 may be made of a transparent conductive material such as metal oxide. The first electrode layer 300 may be formed through various thin film deposition processes known in the art, such as metal organic chemical vapor deposition (MOCVD) and atomic layer deposition (ALD).

The first electrode layer 300 is formed on the upper surface of the substrate 100 or the barrier layer 200 and the upper surface of the first mask patterns M11 and M12, specifically, the upper surface of the first edge mask pattern M11 and the upper surface of the first separator mask pattern M12.

Next, as seen in FIG. 1c, the first masks M11 and M12 are removed from one surface of the substrate 100 or the barrier layer 200. Then, the first electrode layer 300 formed on the upper surface of the first masks M11 and M12 is also removed, and accordingly, the first electrode layer 300 formed on the upper surface of the substrate 100 or the barrier layer 200 is remaining. As a result, a plurality of the first electrode layers 300 spaced apart from each other with the first separator P1 interposed therebetween are obtained for a plurality of unit cells. The pattern of the first separator P1 corresponds to the first separator mask pattern M12, and the first electrode layer 300 is not provided in the first separator P1, so that the upper surface of the substrate 100 or the barrier layer 200 may be exposed at the first separator P1.

The first electrode layer 300 is not provided at one end and the other end of the substrate 100 or the barrier layer 200, which is an area corresponding to the first edge mask pattern M11. Accordingly, the ends of the first electrode layer 300 located at the outermost sides of the one side and the other side are located inside than the ends of the substrate 100 or the barrier layer 200. Therefore, a third separator (P3 in FIG. 1j) region to be described below may be provided in a region corresponding to the first edge mask pattern M11, so that a short circuit problem between the components of the solar cell and other external components is prevented

Next, as seen in FIG. 1d, second masks M21, M22, and M23 are positioned on one surface, for example, an upper surface of the first electrode layer 300.

The process of positioning the second masks M21, M22, and M23 may be performed in the thin film deposition chamber. In this case, the process of positioning the second masks M21, M22, and M23 may include a process of bringing the barrier layer 200 or the substrate 100 and the second masks M21, M22 and M23 into close contact with each other using electrostatic force.

The second masks M21, M22, and M23 include a second edge mask pattern M21, a second contact mask pattern M22, and a second separator mask pattern M23. Portions not provided with the second edge mask pattern M21, the second contact mask pattern M22, and the second separator mask pattern M23 become opening patterns of the second masks M21, M22, and M23.

The second edge mask pattern M21 is formed to correspond to one end and the other end of the substrate 100 or the barrier layer 200, and in particular, may be formed to overlap a portion of the first electrode layer 300 positioned at the outermost sides of one side and the other side. The second edge mask pattern M21 is formed in a pattern different from that of the first edge mask pattern M11, and in particular, is formed to have a wider width than the first edge mask pattern M11.

The second contact mask pattern M22 and the second separator mask pattern M23 are respectively formed on all first electrode layers 300 except for one first electrode layer 300 located at the outermost side. The second contact mask pattern M22 and the second separator mask pattern M23 are formed to have a predetermined interval from each other.

The width of the second edge mask pattern M21 may be greater than that of each of the second contact mask pattern M22 and the second separator mask pattern M23.

As the second masks M21, M22, and M23, a shadow mask known in the art may be used.

Next, as seen in FIG. 1e, a first conductive charge transport layer 400, a light absorption layer 500, and a second conductive charge transport layer 600 are formed in turn on one surface, for example, an upper surface of the first electrode layer 300. That is, the first conductive charge transport layer 400 is formed on the upper surface of the first electrode layer 300, the light absorption layer 500 is formed on an upper surface of the first conductive charge transport layer 400, and the second conductive charge transport layer 600 is formed on an upper surface of the light absorption layer 500. In this case, the first conductive charge transport layer 400 may contact the upper surface of the barrier layer 200 or the substrate 100 through the first separator P1.

The first conductive charge transport layer 400, the light absorption layer 500, and the second conductive charge transport layer 600 may be formed in the thin film deposition chamber at a pressure lower than an atmospheric pressure.

The first conductive charge transport layer 400, the light absorption layer 500, and the second conductive charge transport layer 600 are also formed on upper surfaces of the second masks M21, M22, and M23. That is, the first conductive charge transport layer 400, the light absorption layer 500, and the second conductive charge transport layer 600 are formed on the upper surface of the second edge mask pattern M21, the upper surface of the second contact mask pattern M22 and the upper surface of the second separator mask pattern M23.

In this case, the sum of total thicknesses of the first conductive charge transport layer 400, the light absorption layer 500, and the second conductive charge transport layer 600 may be equal to or less than a thickness of the second mask patterns M21, M22, and M23.

The first conductive charge transport layer 400 may be made of an electron transport layer, the light absorption layer 500 may be made of a perovskite layer, and the second conductive charge transport layer 600 may be made of a hole transport layer.

Alternatively, the first conductive charge transport layer 400 may be made of a hole transport layer, the light absorption layer 500 may be made of a perovskite layer, and the second conductive charge transport layer 600 may be made of a perovskite layer.

The electron transport layer comprises various N-type organic materials known in the art, such as BCP (Bathocuproine), C60, or PCBM (Phenyl-C61-butyric acid methyl ester), various N-type metal oxides known in the art, such as ZnO, c-TiO₂/mp-TiO₂, SnO₂, or IZO, and other various N-type organic or inorganic materials known in the art.

The hole transport layer comprises various P-type organic materials known in the art, such as Spiro-MeO-TAD, Spiro-TTB, polyaniline, polypenol, poly-3,4-ethylenedioxythiophene-polystyrenesulfonate (PEDOT-PSS), poly-[bis(4-phenyl)) (2,4,6-trimethylphenyl)amine] (PTAA), or Poly (3-hexylthiophene-2,5-diyl) (P3HT), various P-type metal oxides known in the art, such as Ni oxide, Mo oxide, V oxide, W oxide, or Cu oxide, and various other P-type organic or inorganic materials known in the art.

The first conductive charge transport layer 400, the light absorption layer 500, and the second conductive charge transport layer 600 may be formed through various thin film deposition processes known in the art, such as CVD (Chemical Vapor Deposition) or ALD

### (Atomic Layer Deposition).

Next, as seen in FIG. 1f, the second masks M21, M22, and M23 are removed from one surface of the first electrode layer 300. Then, the first conductive charge transport layer 400, the light absorption layer 500, and the second conductive charge transport layer 600 formed on the upper surfaces of the second masks M21, M22, and M23 are also removed. Accordingly, the first conductive charge transport layer 400, the light absorption layer 500, and the second conductive charge transport layer 600 formed on the upper surface of the first electrode layer 300 is remaining.

A plurality of first conductive charge transport layers 400 are spaced apart from each other with the contact portion P2 and the second separator P3 interposed therebetween for a plurality of unit cells. Also, a plurality of light absorption layers 500 are spaced apart from each other with the contact portion P2 and the second separator P3 interposed therebetween for a plurality of unit cells. A plurality of second conductive charge transport layers 600 are spaced apart from each other with the contact portion P2 and the second separator P3 interposed therebetween for a plurality of unit cells.

The pattern of the contact portion P2 corresponds to the second contact mask pattern M22, and the pattern of the second separator P3 corresponds to the second separator mask pattern M23. A portion of the upper surface of the first electrode layer 300 may be exposed in the contact portion P2 and the second separator P3.

The first conductive charge transport layer 400, the light absorption layer 500, and the second conductive charge transport layer 600 are not provided at one end and the other end of the substrate 100 or the barrier layer 200. Also, the first conductive charge transport layer 400, the light absorption layer 500, and the second conductive charge transport layer 600 are not provided at the ends of the first electrode layer 300 located at the outermost sides of one side and the other side.

Accordingly, the ends of the first conductive charge transport layer 400, the light absorption layer 500, and the second conductive charge transport layer 600 located at the outermost sides of one side and the other side are located inside than the ends of the first electrode layer 300 located at the outermost sides, and the ends of the first electrode layer 300 located at the outermost sides of one side and the other side are exposed to the outside.

The first conductive charge transport layer 400 obtained by the process of FIG. 1f is formed on the upper surface of the first electrode layer 300. And, the first conductive charge transport layer 400 is formed to fill the first separator P1 so that a lower surface of the first conductive charge transport layer 400 may contact the upper surface of the barrier layer 200. Also, the plurality of first conductive charge transport layers 400 may be spaced apart from each other with the contact portion P2 and the second separator P3 interposed therebetween. As described above, the end of the outermost first conductive charge transport layer 400 may be located inside than the end of the outermost first electrode layer 300, and accordingly, the ends of the first electrode layer 300 at the outermost sides may be exposed to the outside.

Each of the light absorption layer 500 and the second conductive charge transport layer 600 obtained through the process of FIG. 1f may be formed in the same pattern as the first conductive charge transport layer 400 obtained through the process of FIG. 1f.

Next, as seen in FIG. 1g, third masks M31 and M32 are positioned on one surface, for example, an upper surface of the first electrode layer 300.

The process of positioning the third masks M31 and M32 may be performed in the thin film deposition chamber. In this case, the process of positioning the third masks M31 and M32 may include a process of bringing the barrier layer 200 or the substrate 100 and the third masks M31 and M32 into close contact with each other using electrostatic force.

The third masks M31 and M32 include a third edge mask pattern M31 and a third separator mask pattern M32. Portions not provided with the third edge mask pattern M31 and the third separator mask pattern M32 become opening patterns of the third masks M31 and M32.

The third edge mask pattern M31 is formed to correspond to one end and the other end of the substrate 100 or the barrier layer 200, and in particular, may be formed to overlap a portion of the first electrode layer 300 positioned at the outermost sides of one side and the other side. The third edge mask pattern M31 may be formed in the same pattern at the same location as the second edge mask pattern M21. However, the thickness of the third edge mask pattern M31 may be thicker than that of the second edge mask pattern M21.

The third separator mask pattern M32 may be formed on all of the first electrode layers 300 except for one first electrode layer 300 located at the outermost side. The third separator mask pattern M32 is formed to fill the second separator P3, and may be formed in the same pattern at the same position as the aforementioned second separator mask pattern M23. However, a thickness of the third separator mask pattern M32 may be thicker than that of the second separator mask pattern M23.

The width of the third edge mask pattern M31 may be greater than that of the third separator mask pattern M32.

As the third masks M31 and M32, a shadow mask known in the art may be used.

Next, as seen in FIG. 1h, a second electrode layer 700 is formed on one surface, for example, an upper surface of the second conductive charge transport layer 600. At this time, the second electrode layer 700 may contact the first electrode layer 300 through the contact portion P2.

The process of forming the second electrode layer 700 may be performed at a pressure lower than an atmospheric pressure in the thin film deposition chamber.

The second electrode layer 700 is also formed on upper surfaces of the third masks M31 and M32. That is, the second electrode layer 700 is also formed on upper surfaces of the third edge mask pattern M31 and the third separator mask pattern M32.

The second electrode layer 700 may be formed through various thin film deposition processes known in the art, such as MOCVD or ALD.

Next, as seen in FIG. 1i, the third masks M31 and M32 are removed from one surface of the first electrode layer 300. Then, the second electrode layer 700 formed on the upper surfaces of the third masks M31 and M32 is also removed, and accordingly, the second electrode layer 700 formed on the upper surface of the second conductive charge transport layer 600 and the inside of the contact portion P2 is remaining.

A plurality of second electrode layers 700 are spaced apart from each other with the second separator P3 interposed therebetween for a plurality of unit cells. At this time, the second electrode layer 700 of one unit cell is electrically connected to the first electrode layer 300 of another unit cell adjacent thereto through the contact portion P2, and thus a plurality of unit cells are connected in series with each other.

Each of the plurality of unit cells includes the first electrode layer 300, the first conductive charge transport layer 400, the light absorption layer 500, the second conductive charge transport layer 600, and the second electrode layer 700.

The second separator P3 corresponds to the third separator mask pattern M32, and an upper surface of the first electrode layer 300 may be exposed in the second separator P3.

At this time, the second electrode layer 700 is not provided at one end and the other end of the substrate 100 or the barrier layer 200. Also, the second electrode layer 700 is not provided at the ends of the first electrode layer 300 located at the outermost sides of one side and the other side.

Accordingly, the ends of the second electrode layer 700 located at the outermost sides of one side and the other side are located inside than the ends of the first electrode layer 300 located at the outermost side of one side and the other side, the ends of the first electrode layer 300 located at the outermost sides of one side and the other side are exposed to the outside.

Ends of the second electrode layer 700 located at the outermost sides of one side and the other side may be patterned to match the ends of the second conductive charge transport layer 600 located at the outermost sides of one side and the other side.

Next, as seen in FIG. 1j, a first terminal 800a is formed on the first electrode layer 300 located at the outermost side on one side, and a second terminal 800b is formed on the second electrode layer 700 located at the outermost side on the other side.

The region where the first terminal 800a is formed is an area where the first electrode layer 300 provided at the outermost side is overlapped with the second edge mask pattern M21 and the third edge mask pattern M31.

The first terminal 800a may function as a (+) terminal of a plurality of unit cells connected in series, and the second terminal 800b may function as a (−) terminal of a plurality of unit cells connected in series.

Ends of the substrate 100 or the barrier layer 200 at the outermost sides are exposed to the outside to form a third separator P4. Short-circuiting between the outermost unit cell of the solar cell and other external components can be prevented by the third separator P4.

Hereinabove, the embodiments of the present inventive concept have been described in more detail with reference to the accompanying drawings, but the present inventive concept is not limited to the embodiments and may be variously modified within a range which does not depart from the technical spirit of the present inventive concept. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. A method of manufacturing a perovskite solar cell, the method comprising:
a step of preparing a substrate on which a first conductive charge transport layer is formed;
a step of positioning a mask having an opening pattern on the substrate; and
a step of forming a perovskite layer on the substrate and the mask.

2. The method of manufacturing a perovskite solar cell of claim 1, wherein the step of forming the perovskite layer is performed at a pressure lower than an atmospheric pressure.

3. The method of manufacturing a perovskite solar cell of claim 2, wherein the step of positioning the mask having the opening pattern includes bringing the substrate and the mask into close contact with electrostatic force.

4. The method of manufacturing a perovskite solar cell of claim 1, further comprising a step of separating the perovskite layer for a plurality of unit cells by removing the mask and remaining the perovskite layer on the substrate.

5. The method of manufacturing a perovskite solar cell of claim 1, wherein the mask includes an edge mask pattern, a contact mask pattern, and a separator mask pattern,
the edge mask pattern is formed on one end and the other end of the substrate, and
the contact mask pattern and the separator mask pattern are formed to be spaced apart from each other at a center side of the substrate.

6. The method of manufacturing a perovskite solar cell of claim 4, further comprising a step of forming a second conductive charge transport layer on the substrate and the mask before the step of removing the mask, and
a step of separating the second conductive charge transport layer for a plurality of unit cells by remaining the second conductive charge transport layer on the substrate during the step of removing the mask.

7. A method of manufacturing a perovskite solar cell, the method comprising:
a step of preparing a substrate;
a step of positioning a mask having an opening pattern on the substrate; and
a step of forming a first conductive charge transport layer and a perovskite layer on the substrate and the mask.

8. The method of manufacturing a perovskite solar cell of claim 7, wherein the step of forming the perovskite layer is performed at a pressure lower than an atmospheric pressure.

9. The method of manufacturing a perovskite solar cell of claim 8, wherein the step of positioning the mask having the opening pattern includes bringing the substrate and the mask into close contact with electrostatic force.

10. The method of manufacturing a perovskite solar cell of claim 7, further comprising a step of separating the perovskite layer for a plurality of unit cells by removing the mask and remaining the perovskite layer on the substrate.

11. The method of manufacturing a perovskite solar cell of claim 7, wherein the mask includes an edge mask pattern, a contact mask pattern, and a separator mask pattern,
the edge mask pattern is formed on one end and the other end of the substrate, and
the contact mask pattern and the separator mask pattern are formed to be spaced apart from each other at a center side of the substrate.

12. The method of manufacturing a perovskite solar cell of claim 10, further comprising a step of forming a second conductive charge transport layer on the substrate and the mask before the step of removing the mask, and
a step of separating the second conductive charge transport layer for a plurality of unit cells by remaining the second conductive charge transport layer on the substrate during the step of removing the mask.

13. A method of manufacturing a perovskite solar cell, the method comprising:
a step of positioning a first mask on a substrate and forming a first electrode layer separated by a plurality of unit cells using the first mask;
a step of positioning a second mask on the first electrode layer and forming a first conductive charge transport layer, a light absorption layer made of a perovskite compound, and a second conductive charge transport layer, each of which is separated for the plurality of unit cells, using the second mask; and
a step of positioning a third mask on the first electrode layer and forming a second electrode layer separated for the plurality of unit cells using the third mask.

14. The method of manufacturing a perovskite solar cell of claim 13, wherein the first mask includes a first edge mask pattern formed on one end and the other end of the substrate and a first separator mask pattern formed on a center of the substrate,
the second mask includes a second edge mask pattern formed at one end and the other end of the substrate, and a second contact mask pattern and a second separator mask pattern formed at a center of the substrate to be spaced apart from each other, and
the third mask includes a third edge mask pattern formed on one end and the other end of the substrate and a third separator mask pattern formed on a center of the substrate.

15. The method of manufacturing a perovskite solar cell of claim 14, wherein the plurality of first electrode layers are separated with a first separator interposed therebetween,
the plurality of second electrode layers are separated with a second separator interposed therebetween,
the second electrode layer in one of the plurality of unit cells is connected to the first electrode layer in another adjacent one of the plurality of unit cells through a contact portion,
the first separator mask pattern corresponds to the first separator,
the second separator mask pattern and the third separator mask pattern correspond to the second separator, and
the second contact mask pattern corresponds to the contact portion.

16. The method of manufacturing a perovskite solar cell of claim 14, wherein a third separator for preventing short circuit is further provided in an area corresponding to the first edge mask pattern.

17. The method of manufacturing a perovskite solar cell of claim 14, wherein the second edge mask pattern and the third edge mask pattern are formed to overlap with a portion of the first electrode layer provided at an outermost side, and a first terminal is formed in a region overlapped with the portion of the first electrode layer.

18. The method of manufacturing a perovskite solar cell of claim 14, wherein the second contact mask pattern and the second edge mask pattern are formed on the remaining first electrode layers except for one of the plurality of first electrode layers provided at an outermost side.
